(19) United States
(12) Patent Application Publication
(10) Pub. No.: US 2011/0278537 A1
(43) Pub. Date: Nov. 17, 2011

(54) SEMICONDUCTOR EPITAXIAL STRUCTURES AND SEMICONDUCTOR OPTOELECTRONIC DEVICES COMPRISING THE SAME

(76) Inventors: Shih-Chang Lee, Hsinchu City (TW); Rong-Ren Lee, Hsinchu City (TW)

(21) Appl. No.: 13/103,412

(22) Filed: May 9, 2011

(30) Foreign Application Priority Data
May 12, 2010 (TW) 099115262

(51) Int. Cl. H01L 33/04; H01L 31/0248; H01L 29/15

(52) U.S. Cl. 257/13; 257/14; 257/E29.072; 257/E29.022; 257/E33.005; 257/E31.032

(57) ABSTRACT

A semiconductor epitaxial structure includes a substrate; a semiconductor epitaxial stack layers formed on the substrate; and a plurality of semiconductor buffer layers deposited between the substrate and the semiconductor epitaxial layer with a gradually varied composition along one direction; wherein more than one of the semiconductor buffer layers have a patterned surface.

### REFERENCE TO RELATED APPLICATION

This application claims the right of priority based on Taiwan application Serial No. 099115262, filed on May 12, 2010, and the content of which is hereby incorporated by reference.

### TECHNICAL FIELD

The disclosure relates to a semiconductor epitaxial structure, and a semiconductor optoelectronic device which comprises the semiconductor epitaxial structure. More particularly, to a semiconductor epitaxial structure with stress balance and an optoelectronic device which comprises the semiconductor epitaxial structure.

### DESCRIPTION OF BACKGROUND ART

Along with the development of the economy, in order to raise the output of the products and to gain more profit, the labor work has been done by machine gradually. After the industrial revolution, the electricity becomes the main power source, and the way to source of electricity also becomes an international issue. Comparing with the contaminating energy such as the petroleum, the coal, and the nuclear energy, the solar energy makes no pollution and provides energy of 180 watts per meter square to the surface of the earth without being monopolized. Therefore, the solar energy has become one of the most potential energy in the future.

Since the first solar cell produced in Bell's laboratory in the United States in 1954, various kinds of solar cells with different structures were disclosed consecutively. The solar cells could be classified into the silicon-based solar cell, the multi junction semiconductor solar cell, the dye sensitized solar cell, and the organic conductive polymer solar cell and so on in accordance with the difference of the materials. In accordance with FIG. 1, take the conventional silicon-based solar cell device 1 for example, the structure comprises a first electrode 12, a silicon substrate 17, a p-type silicon semiconductor layer 14, an n-type silicon semiconductor layer 15, and a second electrode 16. The sun light 10 illuminates the solar cell device 1 and provides the p-type silicon semiconductor layer 14 and the n-type silicon semiconductor layer 15 the energy which is larger than the band gap of the silicon semiconductor layer. After the atoms in the silicon semiconductor layer absorbing the energy, the free carriers (electrons/holes) are generated. The electrons move toward the n-type silicon semiconductor layer 15, the holes move toward the p-type silicon semiconductor layer 14, and the electric potential difference is produced because the positive and the negative charges accumulate near the p-n junction between the p-type silicon semiconductor layer 14 and the n-type silicon semiconductor layer 15. Due to the electric potential difference, the accumulated electrons flow to the external circuit (not shown in the FIGS.) from the first electrode 12 to the second electrode 16, and the current is produced in the external circuit. Meanwhile, if a load (not shown in the FIGS.) is added in the external circuit, the produced electric energy could be collected and stored. Herein, the combination of the p-type silicon semiconductor layer 14 and the n-type silicon semiconductor layer 15 which could absorb light with a specific wavelength range and produce a current in the external circuit is called a subcell 11.

FIG. 2 shows the spectrum of the solar energy radiation on the surface of the earth. In accordance with the spectrum, besides the visible light, the distribution of the solar energy on the surface of the earth also covers the IR and the ultraviolet light. However, in accordance with the aforementioned operation principle of the solar cell, in the traditional semiconductor solar cell structure, only the solar energy equal to or larger than the band gap of the semiconductor layer could be absorbed. Take the silicon for example, the band gap of the silicon is about 1.12 eV, it can only absorb part of the energy with the wavelength in the IR range in the spectrum. Besides, take the internal loss of the solar cell into consideration, the conversion efficiency of the solar cell is low.

In order to improve the aforementioned problem, a multi junction solar cell is developed and has become one with the highest conversion efficiency.

Refer to FIG. 3, a multi junction tandem solar cell device 3 comprises three subcells (p-n junctions) of Ge/Ga_{0.83}In_{0.17}As/Ga_{0.35}In_{0.65}P in the device. The multi junction tandem solar cell device 3 is stacked by a first electrode 32, a Ge substrate 35, a first subcell 31 with a composition of Ge, a second subcell 33 with a composition of Ga_{0.83}In_{0.17}As, a third subcell 34 with a composition of Ga_{0.35}In_{0.65}P, and a second electrode 36. Wherein, each subcell comprises one p-n junction formed by the combination of one p-type semiconductor layer and one n-type semiconductor layer. Accordingly, the Ge first subcell 31 comprises one p-n junction formed by the combination of one p-type Ge semiconductor material layer 311 (p-Ge) and one n-type Ge semiconductor material layer 312 (n-Ge); the GaInAs second subcell 33 comprises one p-n junction formed by the combination of one p-type Ga_{0.83}In_{0.17}As semiconductor material layer 331 (p-Ga_{0.83}In_{0.17}As) and one n-type Ga_{0.83}In_{0.17}As semiconductor material layer 332 (n-Ga_{0.83}In_{0.17}As); the Ga_{0.35}In_{0.65}P third subcell 34 comprises one p-n junction formed by the combination of one p-type Ga_{0.35}In_{0.65}P semiconductor material layer 341 (p-Ga_{0.35}In_{0.65}P) and one n-type Ga_{0.35}In_{0.65}P semiconductor material layer 342 (n-Ga_{0.35}In_{0.65}P). When the sun light 30 illuminates, in order to let the solar energy absorbed by the aforementioned multi subcells efficiently, the subcell nearest the sun is preferred a subcell with the largest semiconductor band gap, and the band gaps decrease as the distance of each subcell related to the sun increases. Accordingly, the band gap of the Ga_{0.35}In_{0.65}P third subcell 34 is larger than the band gap of the Ga_{0.83}In_{0.17}As second subcell 33, and the band gap of the Ga_{0.83}In_{0.17}As second subcell 33 is larger than the band gap of the Ge first subcell 31.

Besides, there is a first tunnel junction 38 between the first subcell 31 and the second subcell 33 and a second tunnel junction 39 between the second subcell 33 and the third subcell 34. The tunnel junctions are located between the subcells to adjust the resistance between two adjacent subcells, to reduce the charges accumulated near any sides of the two adjacent subcells, and to match the currents of the subcells. Further, to achieve a higher optoelectronic converting efficiency, an anti-reflective layer 37 could be optionally formed between the first electrode 32 and the third subcell 34 to reduce the reflection from the structure surface.

When the sun light 30 passes through the upper Ga_{0.35}In_{0.65}P third subcell 34 with high band gap (˜1.66 eV), the photon with higher energy is absorbed (the range is about from the ultraviolet to the visible light). The central Ga_{0.83}In_{0.17}As second subcell 33 absorbs the photon with the energy from the visible light to the IR region because its band gap is smaller than that of the Ga_{0.35}In_{0.65}P third subcell 34. The central Ga_{0.83}In_{0.17}As second subcell 33 also re-absorbs light with high energy which is not absorbed by the upper Ga_{0.35}In_{0.65}P third subcell 34 and is transmitted from the upper subcell to the central subcell so the solar energy is used more efficiently. Finally, because the Ge first subcell 31 comprises the lower band gap, it could absorb the light with the energy larger than the IR light passing through the upper two subcells again. Referring to FIG. 4, FIG. 4 shows the spectrum response diagram of the multi junction tandem solar cell device 3. One coordinate axis shows the absorbed wavelength and the other coordinate axis shows the percent of the quantum efficiency. The higher the quantum efficiency is, the more efficiently the selected material absorbs the light with the corresponding wavelength and converts it into the electron-hole pairs in the solar cell. As shown in FIG. 4, because the band gaps of the multi-junction solar cell with a composition of Ge/Ga_{0.83}In_{0.17}As/Ga_{0.35}In_{0.65}P increase gradually from the substrate and the range of the absorbed wavelength is broader and overlapped alternatively, the solar energy could be used repeatedly and the solar cell could achieve a very high quantum efficiency in various wavelength range. Therefore, by taking advantage of this kind of stacked multi junction solar cell, the higher conversion efficiency could be achieved.

Nevertheless, when choosing the material of each subcell in one multi junction tandem solar cell, it should consider if the band gaps between the different subcells match as well as the lattice constants of the materials in each subcell to reduce the defects during the manufacturing process and to achieve the higher converting efficiency. Generally, it is considered mismatched when the difference of the lattice constants between the subcell is over 0.05%.

In detail, referring to FIG. 3, the structure of the multi junction tandem solar cell device 3 from bottom to top is the Ge substrate 35, the Ge first subcell 31, the Ga_{0.83}In_{0.17}As second subcell 33, and the Ga_{0.35}In_{0.65}P third subcell 34. The lattice constant of the Ge substrate 35 and the Ge first subcell 31 is 5.658 A so the lattices are matched. However, the lattice constant of the Ga_{0.83}In_{0.17}As second subcell 33 is about 5.722 A, compared with the Ge first subcell 31, the difference of the lattice constant between the adjacent Ga_{0.83}In_{0.17}As second subcell 33 is [(5.722−5.6580)/5.658]×100%≈1.13%, which is lattice mismatched. Accordingly, when epitaxially growing the Ge first subcell 31 and the Ga_{0.83}In_{0.17}As second subcell 33, the growth stress could produce in the device and lead to the lattice defect. Besides, the stress could cause bending or cracking that influences the quality and the yield of the devices.

Except for the multi junction tandem solar cell mentioned above, the epitaxially formed semiconductor optoelectronic device such as the light-emitting diode and so on may also have the similar situation. That is, the inner stress may arise because of the difference of the lattice constant between adjacent epitaxially structures and lead to the lattice defect. Besides, the stress could cause bending or cracking that influences the quality and the yield of the devices.

### SUMMARY OF THE DISCLOSURE

The present disclosure provides a semiconductor epitaxial structure including a substrate; semiconductor epitaxial stack layers deposited on the substrate; and a plurality of semiconductor buffer layers deposited between the substrate and the semiconductor epitaxial stack layers with a gradually varied composition along one direction; wherein more than one of the semiconductor buffer layers have a patterned surface.

### BRIEF DESCRIPTION OF THE DRAWINGS

FIG. 1 illustrates a conventional silicon based solar cell device;

FIG. 2 illustrates a spectrum of the radiation of the solar energy on the surface of earth;

FIG. 3 illustrates a conventional multi junction tandem solar cell device;

FIG. 4 illustrates a spectrum response diagram of the multi junction tandem solar cell device shown in FIG. 2;

FIG. 5 illustrates a multi-junction tandem solar cell device in accordance with one embodiment of the present application;

FIG. 6 illustrates an enlarged sketch of the semiconductor buffer layer combination part of the multi junction tandem solar cell device in accordance with one embodiment of the present application;

FIG. 7 illustrates a light emitting diode device in accordance with one embodiment of the present application;

FIG. 8 illustrates an enlarged sketch of the semiconductor buffer layer combination part of the light emitting diode device in accordance with one embodiment of the present application.

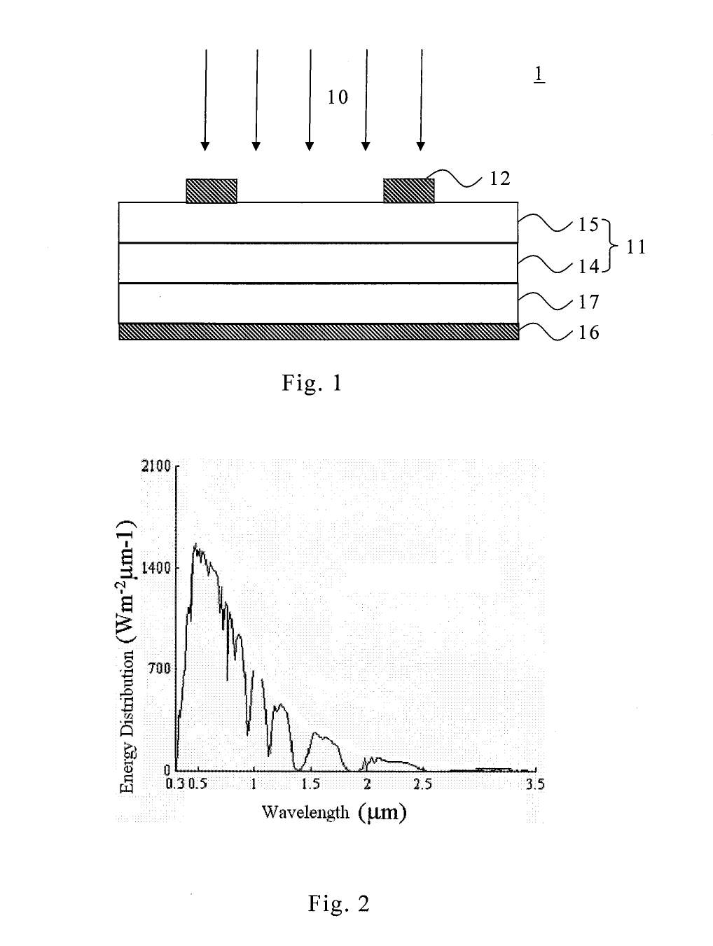

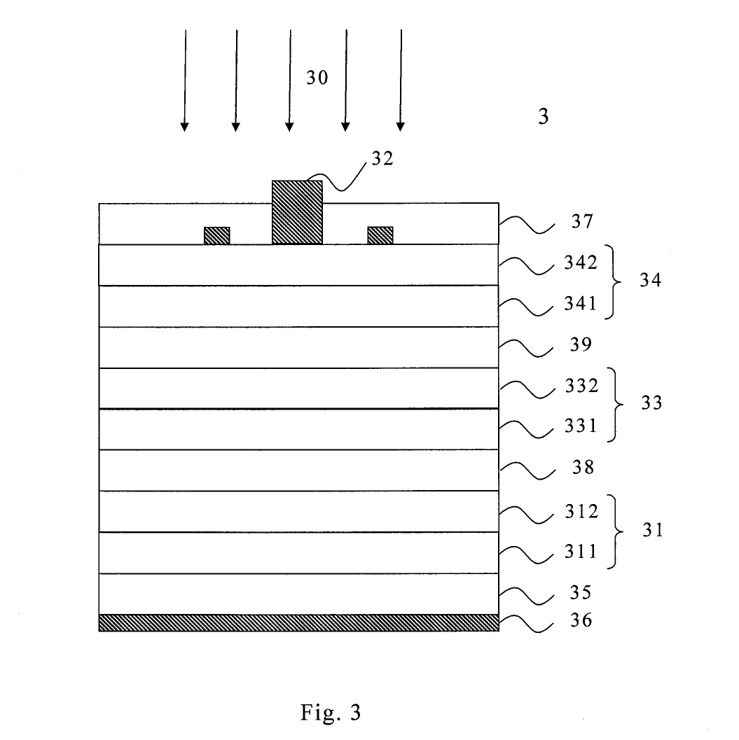

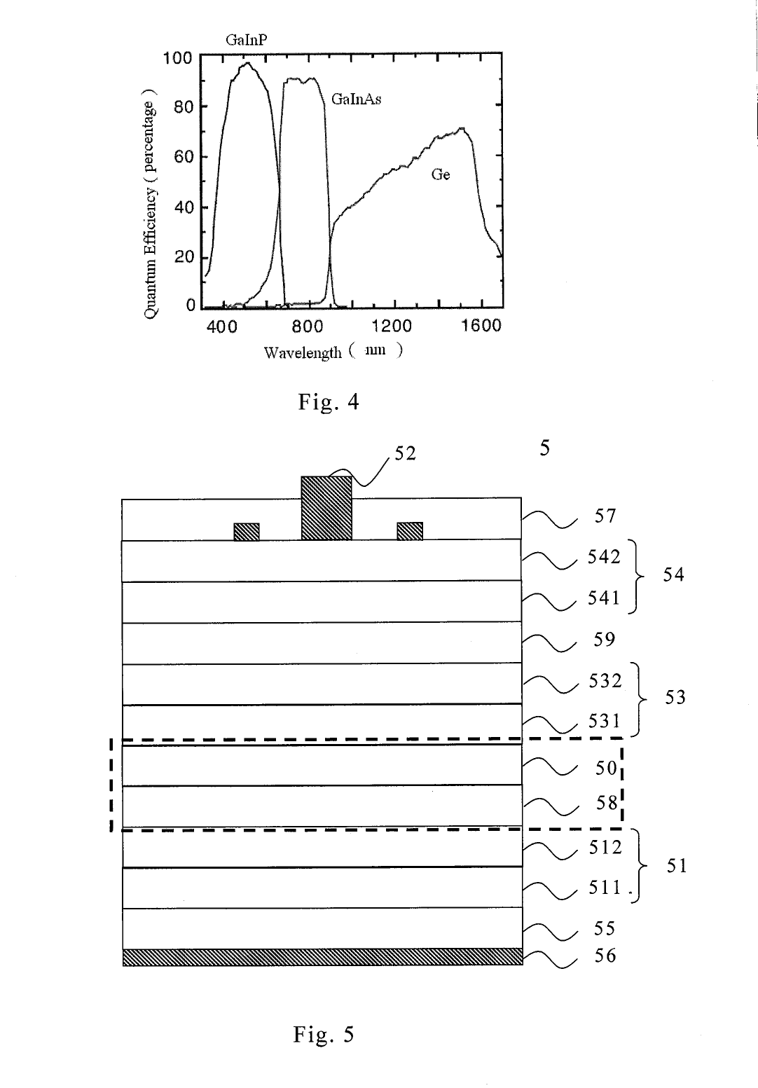

### DETAILED DESCRIPTION OF PREFERRED EMBODIMENTS

The embodiments are described hereinafter in accompany with drawings.

FIG. 5 shows a multi junction tandem solar cell device 5 in accordance with one embodiment of the disclosure. The structure of the multi junction tandem solar cell device 5 from bottom to top is tandem formed by a second electrode 56, a Ge substrate 55, a Ge series first subcell 51, a GaInAs series second subcell 53, a GaInP series third subcell 54, and a first electrode 52. Wherein, each subcell comprises a p-n junction composed of a p-type semiconductor material layer and an n-type semiconductor material layer. Accordingly, the first subcell 51 comprises a first p-n junction composed of a p-type Ge semiconductor material layer 511 and an n-type Ge semiconductor material layer 512; the second subcell 53 comprises a second p-n junction composed of a p-type GaInAs semiconductor material layer 531 and an n-type GaInAs semiconductor material layer 532; the third subcell 54 comprises a third p-n junction composed of a p-type GaInP semiconductor material layer 541 and an n-type GaInP semiconductor material layer 542. The lattice constant of the Ge substrate 55 and the Ge first subcell 51 is 5.658 A, so the structure is lattice matched. However, the lattice constant of the second subcell 53 (GaInAs) is about 5.722 A, and the lattice constant of the third subcell 54 (GaInP) is about 5.722 A. Compared with the Ge first subcell 51, the difference of the lattice constant between the adjacent second subcell 53 is [(5.722−5.6580)/5.658]×100%≈1.13%, which is lattice mismatched.

Besides, a first tunnel junction 58 could be optionally formed between the first subcell 51 and the second subcell 53, and a second tunnel junction 59 could be optionally formed between the second subcell 53 and the third subcell 54. The tunnel junction could be formed optionally between the subcells to adjust the reverse bias voltage resistance between two adjacent subcells, to reduce the charges accumulated at one side of the two adjacent subcells, and to match the currents between the subcells. The structure of the tunnel junction is generally the highly doped p-type or n-type semiconductor layer, and the material of the tunnel junction has a band gap not smaller than that of the subcell which has a smaller band gap in the two adjacent subcells. Preferably, the band gap of the material of the tunnel junction is not smaller than that of the subcell having the larger band gap in the two adjacent subcells. Therefore, to the solar spectrum left from passing the subcells, the tunnel junction is transparent structure, and the remaining solar spectrum could be absorbed by other subcells. In this embodiment, in order to achieve the higher optoelectronic converting efficiency, an anti-reflective layer 57 could be optionally formed between the electrode 52 and the third subcell 54 to reduce the light reflection from the structure surface.

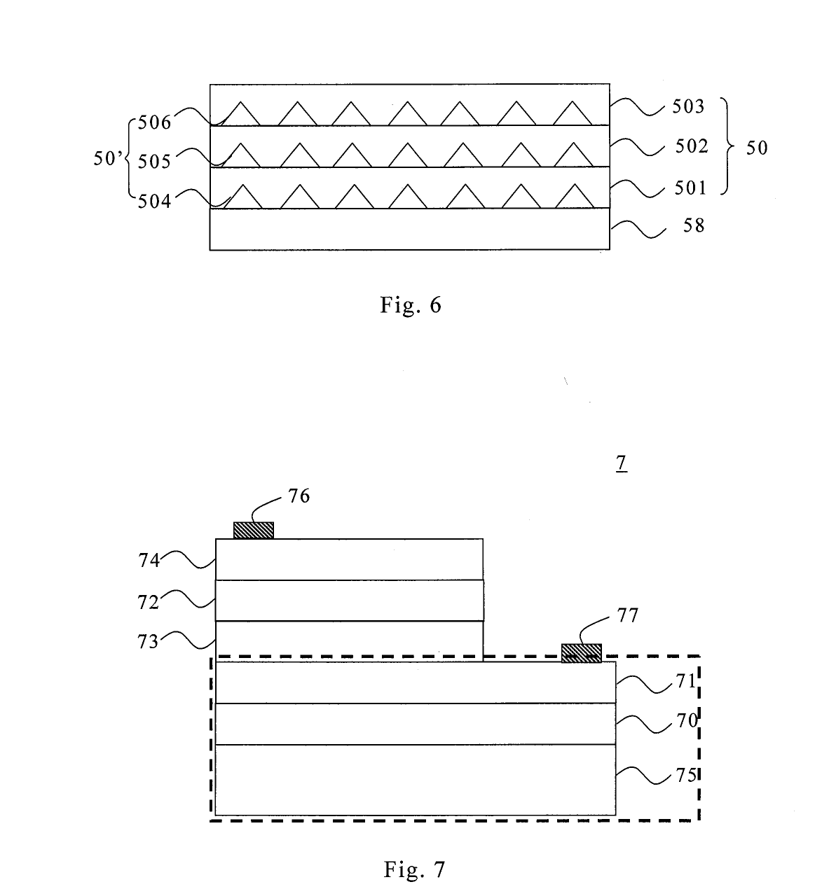

In this embodiment, in order to reduce the stress which leads to the epitaxial defects, a semiconductor buffer layer combination 50 is added between the first subcell 51 and the second subcell 53. The detail of the semiconductor buffer layer combination 50 and the first tunnel junction 58 (shown as the dotted line in the figure) thereunder is shown in FIG. 6. The semiconductor buffer layer combination 50 includes three semiconductor buffer layers 501, 502, and 503. Along the direction from the side close to the first subcell 51 to the side close to the second subcell 53, the lattice constant of the first semiconductor buffer layer 501, the second semiconductor layer 502, and the third semiconductor layer 503 increases from the value smaller and close to the lattice constant 5.658 of the first subcell 51 to the value smaller and close to the lattice constant 5.722 of the second subcell 53. That is, the composition, such as the lattice constant and/or the ratio of the material composition changes along a single direction. Take the embodiment for example, the composition of the three semiconductor buffer layers could be GaₓIn₁₋ₓAs, which is similar to the epitaxial composition of the second subcell 53, and the lattice constant value could be further changed by adjusting the ratio of the Ga element and the In element in the GaₓIn₁₋ₓAs semiconductor structure.

Besides, in this embodiment, a plurality of InAs quantum dots are further formed between each adjacent semiconductor buffer layers to make the semiconductor buffer layer have a patterned surface. The manufacturing procedures are shown as the following: after forming a first quantum dot layer 504 including a plurality of AsIn quantum dots on the first tunnel junction 58, forming a first semiconductor buffer layer 501; after forming a second quantum dot layer 505 including a plurality of AsIn quantum dots on the first semiconductor buffer layer 501, forming a second semiconductor buffer layer 502; after forming a third quantum dot layer 506 including a plurality of AsIn quantum dots on the second semiconductor buffer layer 502, forming a third semiconductor buffer layer 503; finally, forming the p-type GaInAs semiconductor material layer 531 and the semiconductor epitaxial stack layers thereon. Wherein, the quantum dot layer combination could be formed by the conventional method such as Metal-Organic Chemical Vapour Deposition (MOCVD), Molecular Beam Epitaxy (MBE), Liquid Phase Epitaxy (LPE), and Gas Phase Epitaxy (VPE).

Noticeably, while forming the quantum dots, because the quantum dot itself lacks of the crystal defects, it could terminate the upward extension of the defects from the lower epitaxial layer. Besides, by selecting different materials of the quantum dots and the semiconductor buffer layers, the growth stress of the epitaxial layer structure could also be released and the formation of the epitaxial defects could also be reduced. Take the present embodiment for example, by combining the InAs quantum dot layer 50′ having a larger lattice constant and the Ge substrate 55 having a smaller lattice constant, to the GaₓIn₁₋ₓAs semiconductor buffer layer combination 50, because the two different materials have different stresses, the stresses could be balanced and eliminated mutually. Therefore, by adjusting the composition, the quality of the epitaxial structure could be improved.

Next, please refer to FIG. 7, FIG. 7 shows a light-emitting diode device 7 in accordance with another embodiment of the present application. The main structure from bottom to top is tandemly formed by a substrate 75, a first semiconductor material layer 71, an optoelectronic conversion layer 73, and a second semiconductor material layer 72. A first electrode 77 is formed on the first semiconductor material layer 71, and a second electrode 76 is formed on the second semiconductor material layer 72. Besides, a transparent conductive layer 74 could be further optionally formed on the second semiconductor material layer 72 in order to increase the light extraction efficiency and the current diffusion efficiency.

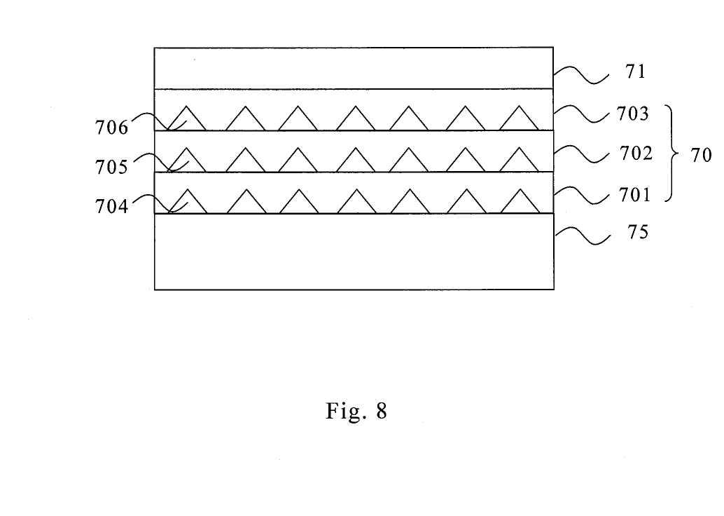

In this embodiment, when the lattice constant of the substrate 75 is mismatched with that of the first semiconductor material layer 71, in order to reduce the formation of the epitaxial defects arisen from the formation of the stress, a semiconductor buffer layer combination 70 could be added between the substrate 75 and the first semiconductor material layer 71. The detail of the semiconductor buffer layer combination 70, the adjacent substrate 75, and the first semiconductor material layer 71 is shown in FIG. 8, the semiconductor buffer layer combination 70 includes three semiconductor buffer layers 701, 702, and 703. Along the direction from the side close to the substrate 75 to the side close to the first semiconductor material layer 71, the lattice constant of the first semiconductor buffer layer 701, the second semiconductor layer 702, and the third semiconductor layer 703 increases from the value close to the lattice constant of the substrate 75 to the value close to the lattice constant of the first semiconductor material layer 71. That is, the composition, such as the lattice constant and/or the ratio of the material composition changes along a single direction. Similar to the former embodiment, the composition of the three semiconductor buffer layers could be the same as the composition of the first semiconductor material layer 71, and the lattice constant could be changed by adjusting the relative ratio of the elements in the composition. Of course, the composition could also be different from the composition of the first semiconductor material layer 71, and the lattice constant could be adjusted by selecting different elements composing the epitaxial layers.

Besides, in this embodiment, a plurality of quantum dots are further formed between each adjacent semiconductor buffer layers to make the semiconductor buffer layer have a patterned surface. The manufacturing procedures are shown as the following: after forming a first quantum dot layer 704 including a plurality of quantum dots on the substrate 75, forming a first semiconductor buffer layer 701; after forming a second quantum dot layer 705 including a plurality of quantum dots on the first semiconductor buffer layer 701, forming a second semiconductor buffer layer 702; after forming a third quantum dot layer 706 including a plurality of quantum dots on the second semiconductor buffer layer 702, forming a third semiconductor buffer layer 73; finally, forming the first semiconductor material layer 71 and the semiconductor epitaxial stack layers thereon. Wherein, the quantum dot layer combination could be formed by the conventional method such as Metal-Organic Chemical Vapour Deposition (MOCVD), Molecular Beam Epitaxy (MBE), Liquid Phase Epitaxy (LPE), and Gas Phase Epitaxy (VPE).

Noticeably, while forming the quantum dots, because the quantum dot itself lacks of the crystal defects, it could terminate the upward extension of the defects from the lower epitaxial layer. Besides, by selecting different materials of the quantum dots and the semiconductor buffer layers, the growth stress of the epitaxial layer structure could also be released and the formation of the epitaxial defects could also be reduced. Take the present embodiment for example, by combining the quantum dot layers with different lattice constants and the semiconductor buffer layer combination 70, because the quantum dot layers and the substrate 75 have different lattice constants, and the quantum dot layers and the substrate 75 have different stresses, the stresses could be balanced and eliminated mutually. Therefore, by adjusting the composition, the quality of the epitaxial structure could be improved.

As shown in the embodiments above, the material of the substrate of the semiconductor epitaxial structure could be but is not limited to the semiconductor material such as GaAs, Ge, SiC, Si, InP, SiGe, ZnO, GaN, and it also could be the metal material or the transparent material such as glass.

Noticeably, the person with ordinary skill in the art could realize that the present invention could be but not limited to the specific kinds of devices shown as the embodiments above such as the multi junction tandem solar cell device and the light-emitting diode device, it could be suitable for any semiconductor epitaxial structure with the lattice constant mismatch to release the stress, to reduce the formation of the epitaxial defects, and to increase the quality of the epitaxial structure. Besides, the patterned semiconductor buffer layer surface is also not limited to be formed by formation of a plurality of the quantum dots, and the semiconductor buffer layer surface could also be patterned by etching, laser sculpturing, or depositing. With the patterned surface, it also achieves the stress released effect. Of course, the number of the semiconductor buffer layers and the quantum dot layers could also be adjusted depends on the suitable situation.

The foregoing description has been directed to the specific embodiments of this disclosure. It is apparent; however, that other alternatives and modifications may be made to the embodiments without escaping the spirit and scope of the disclosure.

What is claimed is:

1. A semiconductor epitaxial structure, comprising:
a substrate;
semiconductor epitaxial stack layers formed on the substrate; and
a plurality of semiconductor buffer layers deposited between the substrate and the semiconductor epitaxial stack layers with a gradually varied composition along a direction;
wherein more than one of the semiconductor buffer layers having a patterned surface.

2. The structure as claimed in claim 1, wherein the direction starts from the substrate to the semiconductor epitaxial stack layers, from the semiconductor epitaxial stack layers to the substrate, or is parallel with the surface of the substrate.

3. The structure as claimed in claim 1, wherein the material of the substrate is selected from one of the semiconductor material, the metal material, or the combination thereof.

4. The structure as claimed in claim 3, wherein the material of the substrate is selected from one of GaAs, Ge, SiC, Si, InP, SiGe, ZnO, GaN.

5. The structure as claimed in claim 1, wherein the composition is the ratio of the elements which composes the semiconductor buffer layers.

6. The structure as claimed in claim 1, wherein the patterned surface is the surface comprising a plurality of quantum dots.

7. The structure as claimed in claim 6, wherein the materials of the semiconductor buffer layers and the materials of the quantum dots are different.

8. A semiconductor optoelectronic device, comprising:
the structure as claimed in claim 1; wherein the semiconductor epitaxial structure further comprising:
a first semiconductor material layer with a first conductivity formed on the substrate; and
a second semiconductor material with a second conductivity formed on the first semiconductor material layer;
a first electrode, formed on the first semiconductor material layer; and
a second electrode, formed on the second semiconductor material layer.

9. The device as claimed in claim 8, further comprising an optoelectronic conversion layer formed between the first semiconductor material layer and the second semiconductor material layer.

10. The device as claimed in claim 8, wherein the semiconductor optoelectronic device is a solar cell device or a light-emitting diode device.
